(19) United States
(12) Patent Application Publication
(10) Pub. No.: US 2018/0076155 A1
(43) Pub. Date: Mar. 15, 2018

(54) Extremely High Frequency Electronic Component

(71) Applicant: DYCONEX AG, Bassersdorf (CH)

(72) Inventors: Eckardt Bihler, Winterthur (CH); Marc Hauer, Uster (CH); Daniel Schulze, Bassersdorf (CH)

(21) Appl. No.: 15/664,656

(22) Filed: Jul. 31, 2017

(30) Foreign Application Priority Data
Sep. 13, 2016 (EP) 16188539.7

(51) Int. Cl. H01L 23/66; H01L 23/14; H01L 23/13; H01P 3/08; H01L 23/498; H01P 3/12; H01P 5/08

(52) U.S. Cl. CPC H01L 23/66; H01L 23/145; H01L 23/13; H01P 3/081; H01L 2223/6616; H01L 23/49838; H01P 3/121; H01P 5/08; H01L 2223/6633; H01L 23/49866

(57) ABSTRACT

A circuit substrate of an extremely high frequency electronic component having an organic substrate material and at least one hollow space incorporated into the substrate material, the hollow space being provided, on at least part of its peripheral surfaces, with a metal layer and acting as a hollow waveguide for electrical signals with a carrier frequency of 10 GHz or higher, and being directly adjacent to an active component part, and thereby being electrically connected with such an active component part, or being electrically connected with it through a metal lead, in particular a strip line projecting into the hollow space.

### CROSS-REFERENCE TO RELATED APPLICATIONS

This patent application claims the benefit of and priority to co-pending European Patent Application No. EP 16188539.7, filed on Sep. 13, 2016 in the European Patent Office, which is hereby incorporated by reference in its entirety.

### TECHNICAL FIELD

The present invention relates to a circuit substrate of an extremely high frequency electronic component that is built on an organic substrate material. It also relates to an extremely high frequency component with such a circuit substrate.

### BACKGROUND

Hollow waveguides are known in the art. They are used as electric lines for extremely high frequencies above 10 GHz. In contrast to other known electrical connections such as, e.g., coaxial cables, hollow waveguides have the lowest losses, since they do not contain any lossy dielectric. The remaining losses in hollow waveguides are caused by the shielding currents arising in the metal walls of the hollow waveguide. Hollow waveguides are made of metal. The higher the conductivity of the metal, the lower the losses are.

Prior art circuit substrates, especially printed circuit boards that are used to connect components with high-frequency signals, use strip or microstrip lines or other waveguide structures. It is characteristic of these waveguides embedded in substrates that there is always a dielectric (the substrate material) that fills the space between the current-carrying conductors. Connecting hollow waveguides with substrates in a way that is as loss-free as possible requires that the electrical connection of the hollow waveguides with the substrates be as good as possible. This is done, e.g., by soldering the hollow waveguide with pads on the substrate. This is also the solution described in U.S. Pat. No. 8,669,834 or in International Publication No. WO 2013/017844.

The present invention is directed toward overcoming one or more of the above-mentioned problems.

### SUMMARY

The present invention has a goal of making available a circuit substrate of the type mentioned above that has improved electrical properties with respect to extremely high frequency signals and that is relatively simple and cost-effective to produce. Similarly, the present invention has a goal of indicating an improved extremely high frequency electronic component.

At least these goals are accomplished by a circuit substrate with the features of claim 1 and by an extremely high frequency component with the features of claim 16, respectively. Expedient embodiments of the present invention are the object of the dependent claims.

The present invention includes directly combining an organic circuit substrate (of the type of conventional printed circuit boards) with conventional hollow waveguides. It also includes embedding such a hollow waveguide directly into the organic circuit substrate, this hollow waveguide being in the form of a hollow space at least part of whose peripheral surfaces are provided with a metal layer. Finally, the invention includes arranging this (at least partly metallized) hollow space directly adjacent to an active component part and directly electrically connected with it, or realizing a signal connection with the component by a metal lead, in particular, a strip line projecting into the hollow space.

The present invention makes it possible to produce millimeter wave substrates that are completely integrated with all necessary components. The shorter distances to the integrated hollow waveguides make it possible to reduce attenuation and improve the efficiency over that of previously known solutions. Simultaneously, manufacturing costs are expected to be lower, which will give the manufacturer better sales margins, and the feature will give him a unique position in the market for millimeter wave applications.

In an embodiment of the circuit substrate that is preferred from the current perspective, the substrate material has a liquid crystal polymer, LCP. In other embodiments, the circuit substrate has a multilayer structure that comprises at least two substrate material layers with a structured metal layer, in particular, a copper layer, between them. A combination with the previously mentioned preferred choice of material provides that a first substrate material layer be in the form of an LCP circuit board with a copper coating on both sides, and a second substrate material layer be in the form of an LCP film that is thinner and lower-melting than the first substrate material layer. Other layers to compensate for required component height differences are also possible.

In other embodiments, the circuit substrate has at least one other structured metal layer, especially in the form of a covering layer. In particular, it is provided that the other metal layer arranged in the form of a covering layer covers at least one section of the hollow space acting as a hollow waveguide, or every such hollow space.

In other expedient embodiments, the hollow space has a rectangular shape, at least in one cut surface perpendicular to the plane of the substrate, especially in two cut surfaces perpendicular to the plane of the substrate and to one another. In particular, the hollow space is configured so that a first side of the cut surface, or at least of one cut surface, has a length in the range between 1 and 4 mm, especially between 1.5 and 3 mm, and a second side of this cut surface has a length between 1 and 7 mm, especially between 2 and 5 mm. If the hollow space is stretched out in the shape of a long trench, its length is determined by the arrangement of the active component parts to be connected, and possibly by a side length of the circuit substrate.

In another embodiment, the hollow space is open, at least at one end, so that it acts as an antenna for extremely high frequency signals. In particular, the hollow space can reach as far as a boundary edge of the circuit substrate and be open there, i.e., act as an antenna. Independent of this, at least one opening for the emission of extremely high frequency signals can be provided in at least one otherwise closed peripheral surface, for instance, the bottom surface or top surface of the hollow waveguide. In particular, one or more emission openings can be arranged in a bottom surface or a top surface of the hollow, especially in a peripheral surface that is not surrounded by organic substrate material.

In another embodiment that is expedient from the current perspective, all peripheral surfaces are essentially completely covered with a metal layer. If, however, additional leads are provided for connection with one or more active component(s), the metal layer is removed around a penetration point of one metal lead projecting into the hollow space, or around every such metal lead, so that the lead or every lead is electrically insulated from the metal layer.

For optimal function of the hollow waveguide, the conductivity of the metal film forming its peripheral surfaces is important, as was mentioned at the beginning of the description. Due to the skin effect, the primary role is played by the layer lying directly on the surface. Therefore, advantageous embodiments provide that the metal film, or at least its surface layer, consists of a highly conductive and corrosion-resistant metal, such as, for instance gold or silver. On the other hand, a base layer of the metal film, even by far the largest part of it, can also consist of a lower conductivity metal.

Further features, aspects, objects, advantages, and possible applications of the present invention will become apparent from a study of the exemplary embodiments and examples described below, in combination with the Figures, and the appended claims.

### DESCRIPTION OF THE DRAWINGS

Other advantages and expedient features of the present invention follow from the following description of sample embodiments, which make reference to the figures. The figures are as follows:

FIG. 1 shows a schematic cross sectional representation of a circuit substrate according to a first sample embodiment;

FIG. 2 shows a schematic cross sectional representation of a circuit substrate according to a second sample embodiment;

FIG. 3 shows a schematic cross sectional representation of a circuit substrate according to a third sample embodiment; and

FIG. 4 shows a schematic perspective representation of an inventive extremely high frequency component according to an embodiment of the present invention.

### DETAILED DESCRIPTION

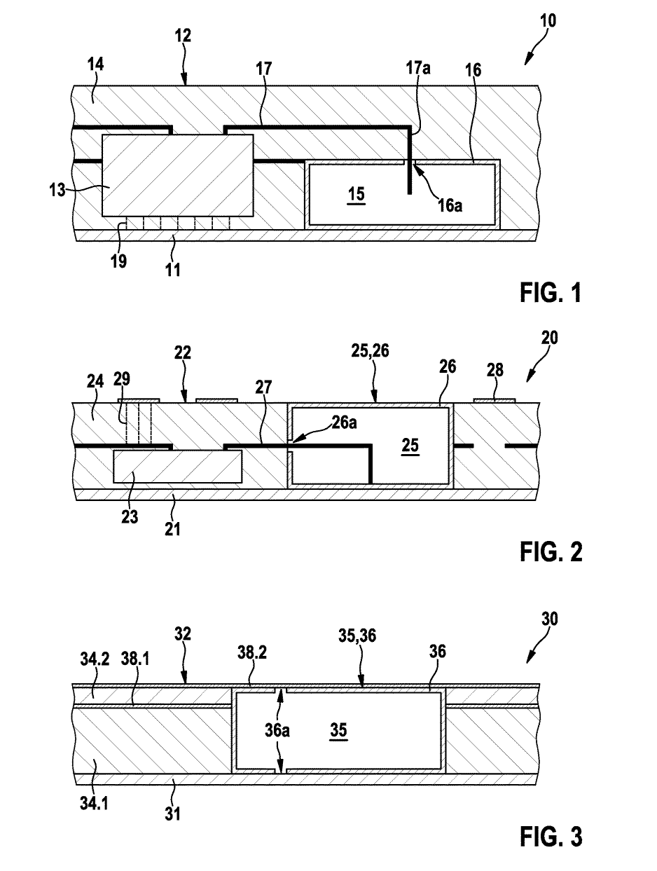

FIG. 1 shows a schematic cross sectional representation of a section through an electronic component or a subassembly 10, in which extremely high frequency signals with a carrier frequency of over 10 GHz are transmitted and processed. A base plate 11, consisting of copper, for example, of a circuit substrate 12 essentially formed from an LCP, has a component part 13 fixed on it, embedded in a thick LCP layer 14. In order to connect the component part thermally and electrically to the base plate 11, a copper-filled feedthroughs 19 can optionally be inserted. Next to the component part 13, located a certain distance from it, there is a hollow space 15 with a rectangular cross section, whose peripheral walls are all completely covered with a metal layer 16—with the exception of a small area 16a of the top surface. Here, a feedthrough section 17a of a microstrip line 17 projects into the hollow space 15.

A coupling section (not shown) couples into the hollow space an extremely high frequency signal, which propagates in the hollow space, causing the latter to act as a hollow waveguide 15/16. The feedthrough offshoot 17a couples the extremely high frequency signal wave transmitted in the hollow waveguide 15/16 into the microstrip line 17 and transfers it to the active component part 13. Incidentally, the active component part 13 can be connected with the base plate 11 through feedthroughs 19.

FIG. 2 shows an embodiment of the present invention largely similar to component 10 according to FIG. 1, namely a component 20, which also comprises an LCP circuit substrate 22 with a base plate 21, and an LCP layer 24, and a hollow space 25 whose peripheral walls have, over almost their entire surface, a metal coating 26, this hollow space 25 forming, together with the metal coating 26, a hollow waveguide 25/26.

In distinction to the component according to FIG. 1, the microstrip line 27 of the component part 23 that is also provided here opens into the hollow waveguide 25/26 not on its top surface but, rather, on a side surface of it. This side surface once again has an interruption 25a in the metal coating 26, similar to that in the top surface of the hollow waveguide 15/16 according to FIG. 1. The association between hollow waveguide 25/26 and microstrip line 27 according to FIG. 2 couples the signal wave into the hollow waveguide 25/26 or couples it out of the hollow waveguide 25/26 in transverse magnetic mode, while the arrangement according to FIG. 1 couples the wave into or out of the hollow waveguide 15/16 in transverse electric mode.

Another difference from the arrangement according to FIG. 1 is that the surface of the LCP layer 24 has a structured metal film 28, for example, made of copper or aluminum, provided on it, to realize other electrical connections within the component 20. Here, the metal layer that covers the hollow space 25 can be realized as part of that structured metal layer 28. The structured metal layer 28 can also be connected with the microstrip line 27 through feedthroughs 29, and be made in the form of an antenna surface (e.g., for a patch antenna).

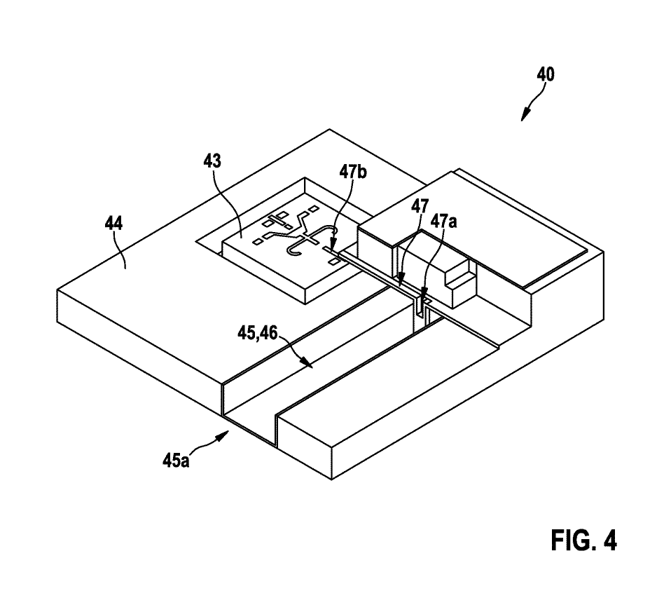

FIG. 3 shows, once again in a cross sectional representation similar to FIGS. 1 and 2, a section of another extremely high frequency component 30 that is made with a circuit substrate 32 that comprises a two-layer structure made of a first LCP layer 34.1 that is thicker and higher melting on a base plate 31, and a second LCP film 34.2 laid over it that is thin and lower melting. The two LCP layers 34.1 and 34.2 have a metal film interlayer 38.1 arranged between them, and a covering metal film layer 38.2 arranged on the surface of the circuit substrate.

The circuit substrate 32 once again has a hollow waveguide 35/36 embedded into it, which consists of a trench 35 having a rectangular cross section and a metal film 36, which almost completely covers the bottom wall and the side walls of the trench and also its top side. FIG. 3 shows, as an example, one extremely high frequency in/out coupling opening 36a in each of the bottom surface and in the top surface.

FIG. 3 does not show an active component part or a lead projecting into the hollow space; however, such components can be provided, and the leads can be realized, for example, by structuring of the metal layers 38.1, 38.2. Incidentally, active component parts need not necessarily (as shown in FIGS. 1 and 2) be embedded into the respective circuit substrate but, rather, they can also be arranged on it or possibly also beneath it.

FIG. 4 shows a perspective schematic illustration of another electronic component 40, whose parts are once again labeled with numbers following those of the other Figures. This component comprises a circuit substrate 44 (whose structure is not shown in detail here) with an embedded active component part 43 and a long, stretched out hollow waveguide 45/46. The hollow waveguide 45/46 has, on one edge of the circuit substrate 44, an open end 45a that acts as an antenna to couple the extremely high frequency signals in and out and a bordering surface of the hollow waveguide 45/46.

Once again, a microstrip line 47 is provided to produce a signal connection between the active component part 43 and the hollow waveguide 45/46. This microstrip line 47 once again also has a feedthrough (via) section 47a projecting into the hollow space of the hollow waveguide, this section serving to couple the extremely high frequency signals from the microstrip line 47 into the hollow waveguide in the wave's transverse magnetic mode (shown in the same way as in FIG. 2). Another via section 47b of the lead or connecting bridge 47 serves to make contact with the component part 43.

For details about material or dimensioning aspects of the possible embodiments of the circuit substrate and the embedded hollow waveguide, see the general embodiments above.

The embodiment of the present invention is not limited to the above-described examples and aspects, but rather many modifications of it are also possible, which lie within the scope of the work of the person skilled in the art.

It will be apparent to those skilled in the art that numerous modifications and variations of the described examples and embodiments are possible in light of the above teachings of the disclosure. The disclosed examples and embodiments are presented for purposes of illustration only. Other alternate embodiments may include some or all of the features disclosed herein. Therefore, it is the intent to cover all such modifications and alternate embodiments as may come within the true scope of this invention, which is to be given the full breadth thereof. Additionally, the disclosure of a range of values is a disclosure of every numerical value within that range, including the end points.

I/We claim:

1. A circuit substrate of an extremely high frequency electronic component, comprising:
an organic substrate material; and
at least one hollow space incorporated into the substrate material, the hollow space being provided, on at least part of its peripheral surfaces, with a metal layer and acting as a hollow waveguide for electrical signals with a carrier frequency of 10 GHz or higher, and being directly adjacent to an active component part, and thereby being electrically connected with such an active component part, or being electrically connected with it through a metal lead including a strip line projecting into the hollow space.

2. The circuit substrate according to claim 1, the substrate material having a liquid crystal polymer, LCP.

3. The circuit substrate according to claim 1, wherein the hollow space has a rectangular shape, at least in one cut surface perpendicular to the plane of the substrate, or especially in two cut surfaces perpendicular to the plane of the substrate and to one another.

4. The circuit substrate according to claim 3, wherein a first side of the cut surface, or of at least one cut surface of the hollow space, has a length in the range between 1 and 4 mm, and a second side of this cut surface has a length between 1 and 7 mm.

5. The circuit substrate according to claim 3, wherein a first side of the cut surface, or of at least one cut surface of the hollow space, has a length in the range between 1.5 and 3 mm, and a second side of this cut surface has a length between 2 and 5 mm.

6. The circuit substrate according to claim 1, wherein the hollow space is open, at least at one end, in such a way that it acts as an antenna for extremely high frequency signals.

7. The circuit substrate according to claim 1, wherein at least one otherwise closed peripheral surface of the hollow waveguide is provided with at least one opening for the emission of extremely high frequency signals.

8. The circuit substrate according to claim 1, wherein all peripheral surfaces are essentially completely covered with a metal layer.

9. The circuit substrate according to claim 8, wherein the metal layer is removed around a penetration point of one metal lead projecting into the hollow space, or around every such metal lead, so that the lead or every lead is electrically insulated from the metal layer.

10. The circuit substrate according to claim 1, wherein the metal layer has silver or gold or an alloy of them, at least on the surface facing the hollow space.

11. The circuit substrate according to claim 1, wherein the metal layer has copper on a surface facing the substrate material.

12. The circuit substrate according to claim 1, with a multilayer structure that comprises at least two substrate material layers with a structured metal layer, including a copper layer, between them.

13. The circuit substrate according to claim 12, wherein a first substrate material layer is in the form of an LCP circuit board with a copper coating on both sides and a second substrate material layer is in the form of an LCP film that is thinner and lower-melting than the first substrate material layer.

14. The circuit substrate according to claim 12, with at least one other structured metal layer, especially in the form of a covering layer of the substrate.

15. The circuit substrate according to claim 14, wherein the other metal layer arranged in the form of a covering layer covers at least one section of the hollow space acting as a hollow waveguide, or every such hollow space.

16. An extremely high frequency electronic component with a circuit substrate according to claim 1, and at least one active circuit component electrically connected to the embedded hollow waveguide.
